(19) United States
(12) Patent Application Publication
(10) Pub. No.: US 2013/0108863 A1
(43) Pub. Date: May 2, 2013

(54) Coated Graphite Article And Reactive Ion Etch Manufacturing And Refurbishment Of Graphite Article

(71) Applicants: Richard A. Cooke, Farmingham, MA (US); Nilesh Gunda, North Chelmsford, MA (US); Steven Donnell, Burlington, MA (US); Yan Liu, Arlington, MA (US)

(72) Inventors: Richard A. Cooke, Farmingham, MA (US); Nilesh Gunda, North Chelmsford, MA (US); Steven Donnell, Burlington, MA (US); Yan Liu, Arlington, MA (US)

(73) Assignee: Entegris, Inc.

(21) Appl. No.: 13/583,316

(22) PCT Filed: Apr. 15, 2011
(86) PCT No.: PCT/US11/32662

§ 371 Date: Sep. 7, 2012

Related U.S. Application Data
(60) Provisional application No. 61/326,469, filed on Apr. 21, 2010.
(60) Provisional application No. 61/326,473, filed on Apr. 21, 2010.
(60) Provisional application No. 61/326,462, filed on Apr. 21, 2010.

(51) Int. Cl. C23C 14/48; H01B 5/14

(52) U.S. Cl. CPC C23C 14/48; H01B 5/14
USPC 428/336; 428/408; 204/192.34; 427/140

(57) ABSTRACT

In accordance with an embodiment of the invention, there is provided a coated graphite article. The article comprises graphite; and a conductive coating overlaying at least a portion of the graphite. The conductive coating comprises a through-thickness resistance of less than about 50 ohms as measured through the thickness of the graphite and the conductive coating. In accordance with another embodiment of the invention, there is provided a method for manufacturing a graphite article comprising a conductive coating. The method comprises treating graphite of the article with a reactive ion etch process; and after treating the graphite with the reactive ion etch process, applying the conductive coating over at least a portion of the graphite. In a further embodiment according to the invention, there is provided a method for refurbishing a graphite article comprising graphite and an overlaying conductive coating. The method comprises removing the overlaying conductive coating of the graphite article with a reactive ion etch process; and applying a new conductive coating over at least a portion of the graphite.

### RELATED APPLICATIONS

This application claims the benefit of U.S. Provisional Application No. 61/326,462, filed on Apr. 21, 2010; and claims the benefit of U.S. Provisional Application No. 61/326,469, filed on Apr. 21, 2010; and claims the benefit of U.S. Provisional Application No. 61/326,473, filed on Apr. 21, 2010. The entire teachings of the above applications are incorporated herein by reference.

### BACKGROUND OF THE INVENTION

Ion implantation techniques are used to introduce impurities into workpieces, such as semiconductor wafers. However, during implantation, particles are generated that may contaminate the workpiece. As discussed in U.S. Patent App. Pub. No. 2009/0179158 A1 of Stone et al., the disclosure of which is hereby incorporated herein by reference in its entirety, chamber liners may be used to line a process chamber in which an ion implant process is performed.

Graphite has conventionally been used as a liner for a process chamber. Every four weeks or so, the graphite liner needs to be replaced in order to prevent excessive contamination on semiconductor wafers that are being manufactured in the ion implant process. The replacement and consequent down-time for the implant tool can be expensive, and the costs are increased by the need to “season” the process chamber after maintenance is performed. Typically, a new implanter or an implanter in which preventive maintenance has just been performed takes too long to season. Many wafers are wasted and down time is extended, at high cost to the customer.

There is therefore an ongoing need for improved protective liners for vacuum chambers and other applications, and techniques of manufacturing and replacing such liners.

### SUMMARY OF THE INVENTION

In accordance with an embodiment of the invention, there is provided a coated graphite article. The article comprises graphite, and a conductive coating overlaying at least a portion of the graphite. The conductive coating comprises a through-thickness resistance of less than about 50 ohms as measured through the thickness of the graphite and the conductive coating.

In further, related embodiments, the article may comprise a liner of a vacuum chamber, such as a liner of a vacuum chamber of an ion implant tool. The vacuum chamber may comprise a particle beam, and at least a portion of the liner that faces the particle beam may comprise the graphite and the overlaying conductive coating. An entire surface of the liner may comprise the graphite and the overlaying conductive coating. The conductive coating may comprise less than about 1 part per million total impurity level; and may comprise less than about 0.1 parts per million total impurity level. The impurity level may comprise permitting greater than about 1 atomic percent of at least one of carbon, silicon, nitrogen and hydrogen. The impurity level may comprise permitting dopants of less than about 1 atomic percent, the permitted dopants comprising at least one of boron, phosphorus and arsenic.

In further, related embodiments, the conductive coating may comprise silicon carbide; and may comprise a carbon to silicon ratio of at least about 40 percent carbon to about 60 percent silicon by atomic percent. The conductive coating may comprise non-stoichiometric silicon carbide. The conductive coating may comprise amorphous hydrogenated silicon carbide (a-SiC:H), and may comprise equal parts silicon to carbon; and may comprise a thickness of within about 50 nm of about 250 nm. The conductive coating may comprise a thickness of less than about 1000 nm. Further, the conductive coating may comprise a thickness of more than about 100 nm. Further, the conductive coating may comprise a thickness of within about 50 nm of about 250 nm; and may comprise a thickness of within about 50 nm of about 500 nm.

In other related embodiments, the graphite may comprise a product produced by a process comprising purifying the graphite before machining the graphite; machining the graphite; and purifying the graphite after machining the graphite. The graphite may comprise graphite based on a carbon starting material of an average grain size of between about 3 microns and about 8 microns prior to graphitization of the graphite; and may comprise graphite based on a carbon starting material of an average grain size of about 5 microns prior to graphitization of the graphite. The article with the conductive coating may comprise a surface producing greater than about 70% densitometry transmission using an optical density tape test; and may comprise a surface producing greater than about 80% densitometry transmission using an optical density tape test. The conductive coating may suppress the growth of nanopillars on the article.

In further, related embodiments, the conductive coating may comprise carbon; and may comprise diamond-like carbon. The conductive coating may comprise a thickness of within about 50 nm of about 500 nm. The conductive coating may comprise amorphous carbon; and may comprise amorphous hydrogenated nitrogen-containing carbon. The conductive coating may comprise up to 25 percent hydrogen by atomic percent, and the conductive coating may comprise a composition based on elements other than hydrogen of at least about 80 percent carbon to about 20 percent nitrogen by atomic percent. The conductive coating may comprise a composition based on elements other than hydrogen of between (i) about 85 percent carbon to about 15 percent nitrogen by atomic percent and (ii) about 90 percent carbon to about 10 percent nitrogen by atomic percent.

In further, related embodiments, the graphite may comprise trace amounts of at least one substance imparted from an ion source; the conductive coating may not comprise the trace amounts of the at least one substance imparted from the ion source; and the article may comprise a surface producing greater than about 70% densitometry transmission using an optical density tape test. The article may comprise a surface producing greater than about 80% densitometry transmission using an optical density tape test. The substance imparted from the ion source may comprise at least one of a photoresist, boron, arsenic, silicon and phosphorus; and may comprise at least one of a backsputtered material from an ion implant process and an evaporated material from an ion implant process.

In another embodiment according to the invention, there is provided a method for manufacturing a graphite article comprising a conductive coating. The method comprises treating graphite of the article with a reactive ion etch process; and after treating the graphite with the reactive ion etch process, applying the conductive coating over at least a portion of the graphite.

In further, related embodiments, treating the article with the reactive ion etch process may comprise treating the article with an Argon Oxygen plasma. The graphite may comprise graphite based on a carbon starting material of an average grain size of between about 3 microns and about 8 microns prior to graphitization of the graphite, such as about 5 microns prior to graphitization of the graphite. The graphite may be produced by purifying graphite for the article before machining the graphite for the article; machining the graphite for the article; and purifying the graphite for the article after machining the graphite for the article. The manufactured article may comprise a surface producing greater than about 70% densitometry transmission using an optical density tape test, such as greater than about 80% densitometry transmission. The article may comprise a liner of a vacuum chamber, such as a vacuum chamber of an ion implant tool. The vacuum chamber may comprise a particle beam, and the method may comprise applying the overlaying conductive coating to at least a portion of the liner that faces the particle beam. The method may comprise applying the overlaying conductive coating to an entire surface of the liner.

In further, related embodiments, the reactive ion etch process may comprise deposition etching at a temperature less than about 150° C. The reactive ion etch process may comprise using at least one of an argon gaseous precursor, an oxygen gaseous precursor and a nitrogen gaseous precursor; and may comprise using radio frequency power. The reactive ion etch process may comprise using an argon gaseous precursor and an oxygen gaseous precursor, using an open baffle partial pressure of about 1.5 mTorr of argon and about 0.5 mTorr for oxygen, using a process baffle pressure of about 5 mTorr, using radio frequency power at about 500 W, for a time of about 10 minutes.

In further, related embodiments, the applied conductive coating may comprise a through-thickness resistance of less than about 50 ohms as measured through the thickness of the graphite and the conductive coating. The conductive coating may comprise silicon carbide; and may comprise amorphous hydrogenated silicon carbide (a-SiC:H) comprising equal parts silicon to carbon and comprising a thickness of within about 50 nm of about 250 nm. The conductive coating may comprise diamond-like carbon; and may comprise a thickness of within about 50 nm of about 500 nm.

In another embodiment according to the invention, there is provided a method for refurbishing a graphite article comprising graphite and an overlaying conductive coating. The method comprises removing at least a portion of the overlaying conductive coating of the graphite article with a reactive ion etch process; and applying a new conductive coating over the at least a portion of the graphite.

In further, related embodiments, the reactive ion etch process may comprise treating the article with an Argon Oxygen plasma. At least one of the graphite and the at least a portion of the conductive coating that is removed may comprise trace amounts of at least one substance imparted from an ion source. The substance imparted from the ion source may comprise at least one of a photoresist, boron, arsenic, silicon and phosphorus; and may comprise at least one of a backsputtered material from an ion implant process and an evaporated material from an ion implant process. The graphite may comprise graphite based on a carbon starting material of an average grain size of between about 3 microns and about 8 microns prior to graphitization of the graphite, such as about 5 microns prior to graphitization of the graphite. The graphite may comprise graphite produced by: purifying graphite for the article before machining the graphite for the article; machining the graphite for the article; and purifying the graphite for the article after machining the graphite for the article. The article may comprise a liner of a vacuum chamber, such as a vacuum chamber of an ion implant tool. The vacuum chamber may comprise a particle beam, and the method may comprise applying the new conductive coating to at least a portion of the liner that faces the particle beam. The method may comprise applying the new conductive coating to an entire surface of the liner. The method may comprise removing the article from the vacuum chamber prior to removing the at least a portion of the overlaying conductive coating.

In further related embodiments, the reactive ion etch process may comprise deposition etching at a temperature less than about 150° C.; and may comprise using at least one of an argon gaseous precursor, an oxygen gaseous precursor, a nitrogen gaseous precursor, a fluorine gaseous precursor, and a chlorine gaseous precursor. The reactive ion etch process may comprise using radio frequency power. The reactive ion etch process may comprise using an argon gaseous precursor, an oxygen gaseous precursor, and a carbon tetrafluoride gaseous precursor, using an open baffle partial pressure of about 1 mTorr of argon and about 0.5 mTorr for oxygen and about 1.5 mTorr for carbon tetrafluoride, using a process baffle pressure of from about 5 mTorr to about 15 mTorr, using radio frequency power at about 500 W, for a time of from about 10 minutes to about 30 minutes. The method may further comprise performing an additional cleaning process prior to performing the reactive ion etch process. The additional cleaning process may comprise at least one of an aqueous ultrasonic cleaning, a high temperature purification, a carbon dioxide blasting, a bead blasting and a slurry blasting. The reactive ion etch process may comprise using an argon/oxygen/carbon tetrafluoride plasma; which may comprise at least about 10% carbon tetrafluoride, at least about 30% carbon tetrafluoride, and at least about 60% carbon tetrafluoride. Once refurbished, the article may comprise a surface producing greater than about 70% densitometry transmission using an optical density tape test, such as greater than about 80% densitometry transmission.

In further, related embodiments, the new applied conductive coating may comprise a through-thickness resistance of less than about 50 ohms as measured through the thickness of the graphite and the conductive coating. The conductive coating may comprise silicon carbide; and may comprise amorphous hydrogenated silicon carbide (a-SiC:H) comprising equal parts silicon to carbon and comprising a thickness of within about 50 nm of about 250 nm. The conductive coating may comprise diamond-like carbon; and may comprise a thickness of within about 50 nm of about 500 nm.

In another embodiment according to the invention, there is provided a coated graphite article. The article comprises graphite comprising trace amounts of at least one substance imparted from an ion source; and a conductive coating overlaying at least a portion of the graphite, the conductive coating not comprising the trace amounts of the at least one substance imparted from the ion source. The article comprises a surface producing greater than about 70% densitometry transmission using an optical density tape test.

In further, related embodiments, the article comprises a surface producing greater than about 80% densitometry transmission using an optical density tape test. The substance imparted from the ion source may comprise at least one of a photoresist, boron, arsenic, silicon and phosphorus; and may comprise at least one of a backsputtered material from an ion implant process and an evaporated material from an ion implant process.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1 illustrates a technique of measuring through-thickness resistance of a conductive coating in accordance with an embodiment of the invention.

FIG. 2 is a graph of through-thickness resistance versus coating thickness for a silicon carbide coating, in accordance with an embodiment of the invention.

FIG. 3 is a scanning electron micrograph of several different thicknesses of silicon carbide coatings in accordance with an embodiment of the invention.

FIG. 4 is a scanning electron micrograph of a coating of diamond-like carbon over underlying graphite, in accordance with an embodiment of the invention.

FIG. 5 is a graph of optical transmission percentages for several different thicknesses of silicon carbide coatings in accordance with an embodiment of the invention.

FIG. 6 is a set of scanning electron micrograph images showing the effect of ion beam bombardment on graphite, such as the type of graphite that may be coated in accordance with an embodiment of the invention.

FIG. 7 is a chart of energy dispersive X-ray spectroscopy (EDS) results for characterizing a sample group of used graphite liner components to be refurbished in accordance with an embodiment of the invention.

FIG. 8 shows results of cleaning the components of FIG. 7 using reactive ion etch refurbishment in accordance with an embodiment of the invention, with the results given as EDS figures for atomic percent of each species present.

FIG. 9 shows further results of cleaning the components of FIG. 7 using the reactive ion etch refurbishment in accordance with an embodiment of the invention, with the results given as electrical resistances for each component.

FIG. 10 is a scanning electron micrograph image of one of the components of FIG. 7 before and after reactive ion etch refurbishment in accordance with an embodiment of the invention.

FIG. 11A is a chart showing the effects of several different reactive ion etch refurbishment procedures performed on the component shown in FIG. 10, in accordance with an embodiment of the invention.

FIG. 11B is a diagram showing the results of FIG. 11A in graphical form, in accordance with an embodiment of the invention.

FIG. 12 is a scanning electron micrograph image of the microstructure of several graphite samples prior to pre-cleaning by a reactive ion etch process in accordance with an embodiment of the invention.

FIG. 13 is a scanning electron micrograph image of the microstructure of a graphite sample after pre-cleaning by a reactive ion etch process in accordance with an embodiment of the invention.

FIG. 14 is a set of photographs of the results of an optical density tape test performed on the graphite samples of FIG. 12 before and after reactive ion etch treatment in accordance with an embodiment of the invention.

### DETAILED DESCRIPTION OF THE INVENTION

A description of example embodiments of the invention follows.

In an embodiment according to the invention, there is provided a material for lining the beam line of an ion implant tool or other tool, which may be useful wherever a high conductivity graphite liner is desirable. The material combines a high purity graphite with a surface coating technology that results in low production of undesirable particles when the liner is used in the ion implant or other tool. The graphite may be optimized for implant processes. The liner results in reduced machine downtime during a preventative maintenance operation due to shortened seasoning time of the process chamber. Further, the ultra-clean liner may result in reduced particles on a semiconductor wafer that is being processed by an ion implant tool.

By having a high conductivity, a liner in accordance with an embodiment of the invention reduces the tendency for charge to build up on the liner, which can cause an ion beam used in the ion implant tool to deflect from its intended path. An article according to an embodiment of the invention may be used in a wide variety of different possible applications, for example as a liner of a vacuum chamber, such as in an ion implant tool. Where a particle beam is used in the vacuum chamber, at least the portion of the liner that faces the particle beam may comprise graphite and an overlaying conductive coating, or the entire surface of the liner may comprise the graphite and the overlaying conductive coating. Further, such liners may be manufactured and/or refurbished in accordance with techniques described herein.

An embodiment according to the invention may comprise graphite coated with a thin layer of highly conductive material, which may be used as a liner for a process chamber. Traditionally, uncoated graphite was used for similar purposes. The advantages of a coated graphite liner in accordance with an embodiment of the invention over a traditional, uncoated graphite liner include the ability to achieve a higher level of surface purity, to reduce particle formation in use of the liner, to improve surface strength against erosion from ion bombardment, and to provide a shorter seasoning time and a longer lifetime of the liner. The chamber liner may reduce the time-to-first wafer, and may reduce arcing on the surface of the liner.

In accordance with an embodiment of the invention, the liner may comprise a coated graphite article, which includes graphite and a conductive surface coating. The conductive surface coating may be formed of a high purity, conductive material, with a suitable composition such as described herein, and having a coating thickness that keeps the conductivity of the liner suitably high, as described below. The underlying graphite may be formed from a carefully selected graphite starting material and be purified as described below.

In accordance with another embodiment of the invention, there is provided a technique for manufacturing and/or refurbishing a liner of a beam line of an ion implant tool or other tool, which may be useful wherever a low particulating graphite liner is desirable. A technique of manufacturing and/or refurbishing a liner may be combined with a high purity graphite optimized for implant processes, and may result in low production of undesirable particles when the liner is used in the ion implant or other tool. Parts can be refurbished to a like-new condition with minimal ablation and contamination. The technique results in reduced machine downtime during a preventative maintenance operation due to shortened seasoning time of the process chamber. Further, an ultra clean liner produced or refurbished by such a technique may result in reduced particles on a semiconductor wafer that is being processed by an ion implant tool.

Techniques in accordance with an embodiment of the invention may include using a reactive ion etch process to treat graphite prior to applying a coating; and may include using a reactive ion etch process to refurbish a used graphite liner, which may include an overlaying conductive coating. The reactive ion etch process may include an Argon Oxygen plasma, and may be optimized for low particulation as described below. A refurbishment process may return graphite used in a liner to as-new condition with minimal impact on dimensional control. Such a technique, and liner manufacturing techniques, may be used with a specially selected graphite starting material and purification for the graphite, as discussed below. Further, reactive ion etch techniques of manufacturing and refurbishing may be used with graphite liners that are coated with a highly conductive coating, such as those set forth herein.

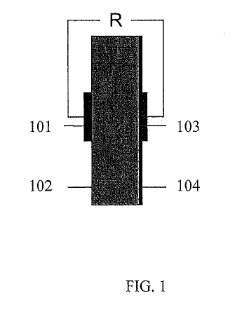

FIG. 1 illustrates a technique of measuring through-thickness resistance of a conductive coating in accordance with an embodiment of the invention. The conductive (non-insulating) coating of an embodiment according to the invention may comprise a through-thickness resistance of less than about 50 ohms as measured through the thickness of the graphite and the conductive coating. As used herein, “through-thickness resistance” may be measured by attaching a test lead of a digital multimeter to an uncoated spot on the underlying graphite, and attaching the other lead of the digital multimeter on the coated surface, or on a conductive tape patch on the coated surface (for example, a 0.25 by 0.25 cm conductive tape patch). For example, with reference to FIG. 1, a resistance R is measured between a test lead 101 on an uncoated spot on the graphite 102, and a test lead 103 on the surface of the conductive coating 104.

In accordance with an embodiment of the invention, the conductive coating may have a high level of purity. For example, the conductive coating may comprise less than about 1 part per million total impurity level, and in particular may comprise less than about 0.1 parts per million total impurity level. The impurity level may comprise permitting greater than about 1 atomic percent of carbon, silicon, nitrogen and/or hydrogen. Further, the impurity level may comprise permitting dopants of less than about 1 atomic percent, such as boron, phosphorus and/or arsenic. In accordance with an embodiment of the invention, the conductive coating may comprise several different possible types of compositions. The coating may comprise a Silicon-Carbon coating having a ratio of about 50:50 Carbon to Silicon by atomic percent, or higher than a 40:60 Carbon to Silicon ratio, such as a higher ratio than 50:50 Carbon to Silicon. Other coatings may be used, particularly coatings having the purity and conductivity characteristics described above. For example, an embodiment according to the invention may use a silicon carbide coating including SilcoMax™, manufactured by Entegris Specialty Coatings of Burlington, Mass., U.S.A. For example, SilcoMax™ with a composition of about 50 Si:50 C (by atomic percent) can be deposited as a conductive coating to a thickness of about 300 nm, which has a through-thickness resistance of about 10 ohms. Further, the coating may comprise a diamond-like carbon coating. Other pure (or essentially pure) carbon coatings may be used, particularly coatings having the purity and conductivity characteristics described above. For example, diamond-like carbon can be deposited as a conductive coating to a thickness of about 500 nm, which has a through-thickness resistance of less than about 50 ohms. Further, the coating may comprise amorphous carbon. In addition, rather than a pure carbon coating, the coating may comprise amorphous hydrogenated nitrogen-containing carbon, or amorphous nitrogen-doped carbon. The amorphous hydrogenated nitrogen-containing carbon may include up to 25% hydrogen by atomic percent, and the composition based on elements other than hydrogen may have a ratio of 80:20 carbon to nitrogen by atomic percent or higher ratio of carbon to nitrogen (not including the hydrogen), preferably a ratio of about 85:15 to about 90:10 carbon to nitrogen (not including the hydrogen).

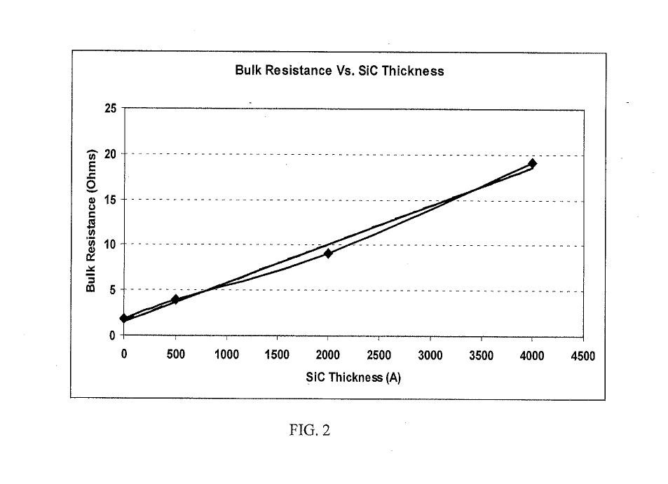

FIG. 2 is a graph of through-thickness resistance versus coating thickness for a SiC coating, in accordance with an embodiment of the invention. The maximum desirable coating thickness for a conductive coating in accordance with an embodiment of the invention may be determined based on the bulk resistivity (or, similarly, the through-thickness resistance) of the coating: that is, the lower the bulk resistivity (or through-thickness resistance) of the material, the thicker the coating may be while still achieving a desirably high level of conductivity. With reference to the graph of FIG. 2, it can be seen based on the slope of the graph that the SiC coating of the graph could be used with a thickness up to about 10,000 Angstoms (i.e., 1000 nm or 1 micron), which is the approximate thickness at which the coating's through-thickness resistance would begin to exceed about 50 ohms. However, coatings with lower bulk resistivity could be made thicker while still achieving a desirably high coating conductivity. For example, an amorphous hydrogenated nitrogen-containing carbon coating could have a relatively low bulk resistivity, and thus could be made relatively thick while still achieving a desirably high coating conductivity. Although a coating should be thin enough to provide a high conductivity, it should be thick enough to prevent the increased particulation that can occur with thinner coatings. Further, if the coating is too thick, it could have undesirable flaking because of adhesion problems. For example, the coating may comprise a thickness of less than about 1000 nm; and may comprise a thickness of more than about 100 nm. Particularly good results are believed to be obtained with a conductive coating made of plasma-enhanced chemical vapor deposition (PECVD) amorphous hydrogenated silicon carbide (a-SiC:H), having equal parts silicon to carbon, and a thickness of about 250 nm+/−about 50 nm; although other coatings may be used. Where amorphous hydrogenated silicon carbide (a-SiC:H) is used, the material may include as much as 15% hydrogen by atomic percent, with the remainder of the material being equal parts silicon to carbon. The conductive coating may be as stoichiometric as possible, or may comprise non-stoichiometric silicon carbide. Further, particularly good results are believed to be obtained with a diamond-like carbon coating having a thickness of about 500 nm+/−about 50 nm; although other coatings may be used.

In accordance with an embodiment of the invention, the coating may be formed by chemical vapor deposition (CVD) or physical vapor deposition (PVD). The coating may comprise high purity materials, such as amorphous or nano-crystalline silicon-based alloys: silicon, silicon-carbon, silicon-nitrogen-carbon, and/or silicon-oxygen-carbon; or materials such as diamond-like carbon, amorphous carbon or other pure (or essentially pure) forms of carbon. The coating process parameters may include: low temperature deposition (such as less than about 150° C.); radio frequency or low frequency power; gaseous silicon and hydrocarbon precursors, and/or oxygen and/or nitrogen gaseous precursors, or carbon precursors; a coating thickness of a few hundred angstroms to a few thousand angstroms or more; and a variety of possible voltages, pressures and gaseous precursor flow rates, as will be appreciated by those of skill in the art. At least the beam-facing side of the liner may be coated. It may be additionally advantageous to coat the back (non-beam-facing) side of the liner in order to reduce particles produced by handling.

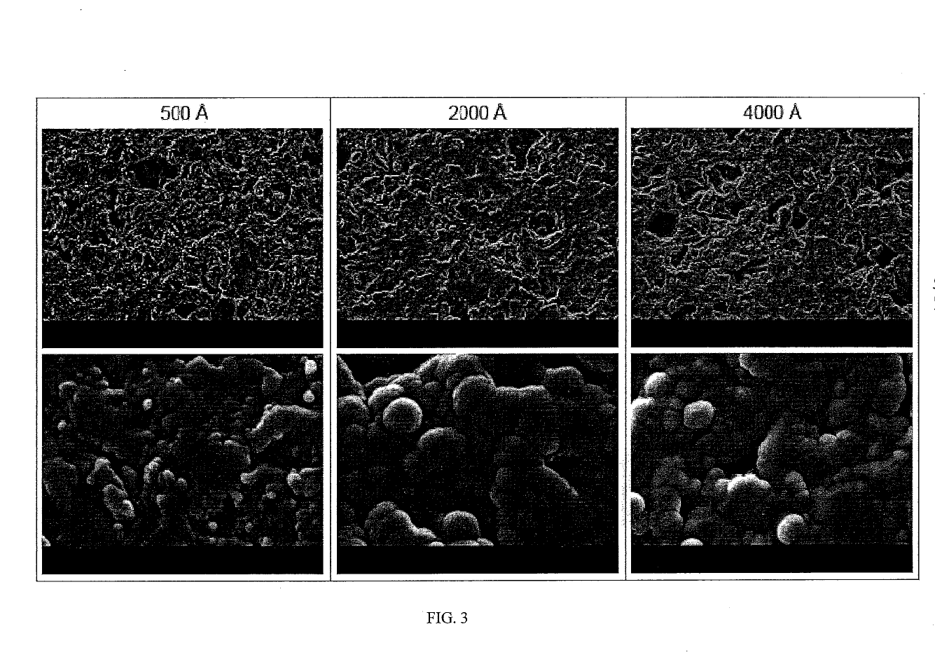

FIG. 3 is a scanning electron micrograph of several different thicknesses of SiC coatings in accordance with an embodiment of the invention. The surfaces of coatings of 500 angstroms, 2000 angstroms and 4000 angstroms thickness (50 nm, 200 nm and 400 nm) are shown, with a scale of 10 μm in the upper three diagrams and a scale of 1 μm in the lower three diagrams.

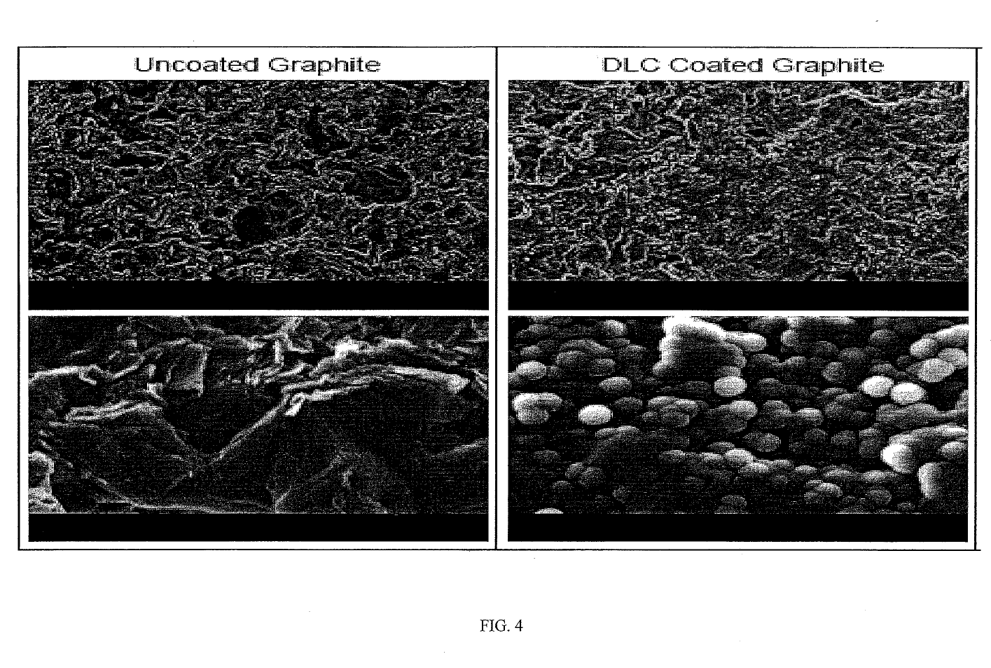

FIG. 4 is a scanning electron micrograph of a coating of diamond-like carbon over underlying graphite, in accordance with an embodiment of the invention. A surface coating of 2000 angstroms thickness (200 nm) is shown in the right column, with a scale of 10 μm in the upper diagram and a scale of 1 μm in the lower diagram; while the underlying (uncoated) graphite is shown in the left column, with a scale of 10 μm in the upper diagram and a scale of 1 μm in the lower diagram.

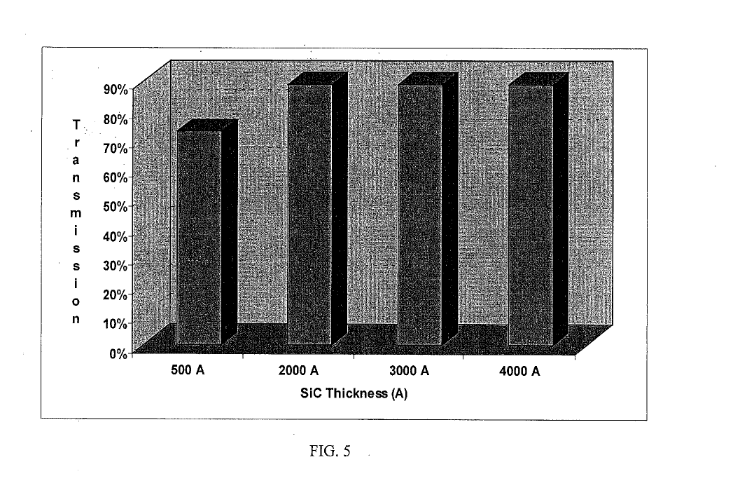

In accordance with an embodiment of the invention, the conductive coating and the underlying graphite may be optimized for producing a low level of particulation. Particle production can be detrimental to manufacturing processes such as semiconductor manufacturing processes in which the liner may be used. FIG. 5 is a graph of optical transmission percentages for several different thicknesses of SiC coatings in accordance with an embodiment of the invention. The transmission percentages provide a measure of the particle production of the liner. In particular, an “optical density tape test” may be used to measure particle production. In such a test, a surface of a liner is taped, for example with Scotch® brand #600 tape, and the tape is then peeled off. (Scotch® tape is manufactured by 3M Corporation of Maplewood, Minn., U.S.A.). The “darkening” of the tape by the particles is then evaluated using a densitometer, for example an X-Rite densitometer (sold by X-Rite, Inc. of Grand Rapids, Mich., U.S.A.), which provides an optical density measurement of the particles produced by the liner and captured on the tape. The densitometer may, for example, provide a reading of optical density, which is the base-ten logarithm of the transmission (T=I/I₀) through the tape; an optical density of 0 corresponds to 100% transmission through the tape, an optical density of 1 corresponds to 10% transmission through the tape, an optical density of 2 corresponds to 1% transmission through the tape, and so forth. As can be seen, a SiC coating of 500 angstoms thickness (50 nm) achieves a transmission of about 70%, while coatings of 2000 angstrom, 3000 angstrom and 4000 angstrom (200 nm, 300 nm and 400 nm) achieve transmission values of greater than about 80%, which correspond to higher transmission through the tape and therefore to lower levels of particles trapped on the tape. Thus, in the graph of FIG. 5, graphite coated with thicker SiC exhibited lower particulation than graphite coated with thinner SiC. In accordance with an embodiment of the invention, a graphite article may comprise a surface producing greater than about 70% densitometry transmission using an optical density tape test; including a surface producing greater than about 80% densitometry transmission. Further, such transmission percentages may be obtained after exposure to an ion beam, which may have been directed at the graphite article at a perpendicular or other incident angle.

In accordance with an embodiment of the invention, the underlying graphite may be produced based on a careful selection of graphite starting material, and may then be purified by a special technique. A low etch rate graphite material is desirable in order to reduce sputtering. In particular, the graphite may comprise graphite based on a carbon starting material of an average grain size of between about 3 microns and about 8 microns prior to graphitization of the graphite, for example an average grain size of about 5 microns. The graphite may be semiconductor grade graphite. The graphite may be produced by a process comprising purifying the graphite before and after machining the graphite. As used herein, “purifying” graphite means to treat graphite in order to remove undesirable impurities. For example, rock or other undesirable impurities may be removed from the graphite using a process that includes exposing the graphite to a high temperature chlorine gas environment. It will be appreciated that other techniques of purifying graphite may be used. As used herein, “machining” graphite means milling, grinding or otherwise mechanically machining the graphite.

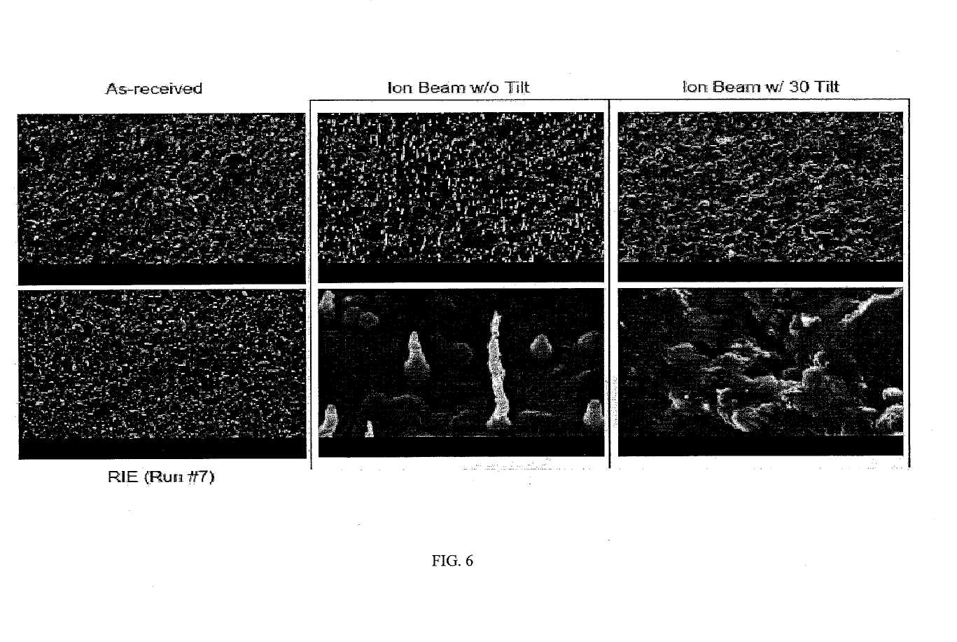

FIG. 6 is a set of scanning electron micrograph images showing the effect of ion beam bombardment on graphite, such as the type of graphite that may be coated in accordance with an embodiment of the invention. In these experiments, the ion beam bombardment is intended to simulate the effect of using the liner in an actual ion implant tool. In the top row of FIG. 6, from left to right, are images of: a graphite sample as received (left); the same sample having undergone an ion beam bombardment with no tilt to the sample (middle); and the same sample having undergone an ion beam bombardment with the sample tilted 30 degrees (that is, an ion beam incident angle of 60 degrees) (right). In the bottom row of FIG. 6 are images corresponding to the images in the top row but at a ten times greater magnification (1 μm scale in the bottom row, 10 μm scale in the top row). The conditions of the ion beam etching for FIG. 6 were an Argon flow rate of 6 sccm (standard cubic centimeters per minute); a process pressure of 1.7 E-4 torr; a beam voltage of 500 V; a beam current of 80 mA; an acceleration voltage of 60 V; an etching time of 2 hours; and sample tilting of 0 or 30 degrees (or ion beam incident angle, 90 or 60 degrees). Using such conditions with the sample shown in FIG. 6 and others, it was found that the graphite surface was smoothed, with less pores and fewer loose particles, by the ion beam bombardment; it was also seen that high aspect ratio nanopillar-type structures occurred on the graphite in some cases under ion beam bombardment (see FIG. 6, bottom middle image). However, sample tilting of 30 degrees resulted in a higher etch rate and suppressed the growth of nanopillars (see FIG. 6, bottom right image). In addition, a highly conductive coating in accordance with an embodiment of the invention may be used to suppress the growth of such nanopillars.

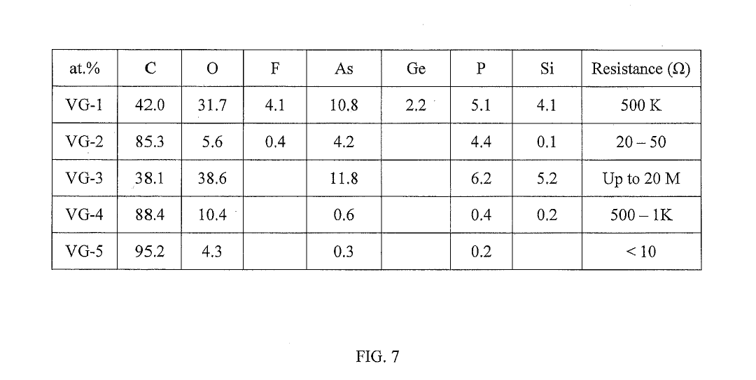

In accordance with another embodiment of the invention, there is provided a technique for manufacturing and/or refurbishing a liner of a beam line of an ion implant tool or other tool, which may be useful wherever a low particulating graphite liner is desirable. Techniques in accordance with an embodiment of the invention may include using a reactive ion etch process to treat graphite prior to applying a coating; and may include using a reactive ion etch process to refurbish a used graphite liner, which may include an overlaying conductive coating. An embodiment according to the invention may be used to clean used graphite liners. FIG. 7 is a chart of energy dispersive X-ray spectroscopy (EDS) results for characterizing a sample group of used graphite liner components, labeled here as VG-1 through VG-5, which are to be refurbished in accordance with an embodiment of the invention. The components fall into three categories of contamination: highly contaminated (VG-1 and VG-3); moderately contaminated (VG-2 and VG-4); and lightly contaminated (VG-5). The categories of contamination are reflected in the amounts of contaminants present (given in atomic percent of each species present), such as oxygen, fluorine, arsenic, germanium, phosphorus and silicon; by a reduced amount of carbon remaining in the component (given in atomic percent); and by an increased electrical resistance, given in ohms.

In accordance with an embodiment of the invention, the used graphite liner components of FIG. 7 were cleaned by reactive ion etch, at high pressure with low frequency and a high voltage level of the power supply. The total cleaning time was two hours and fifteen minutes for sample VG-1, and 30 minutes for samples VG-2 through VG-5.

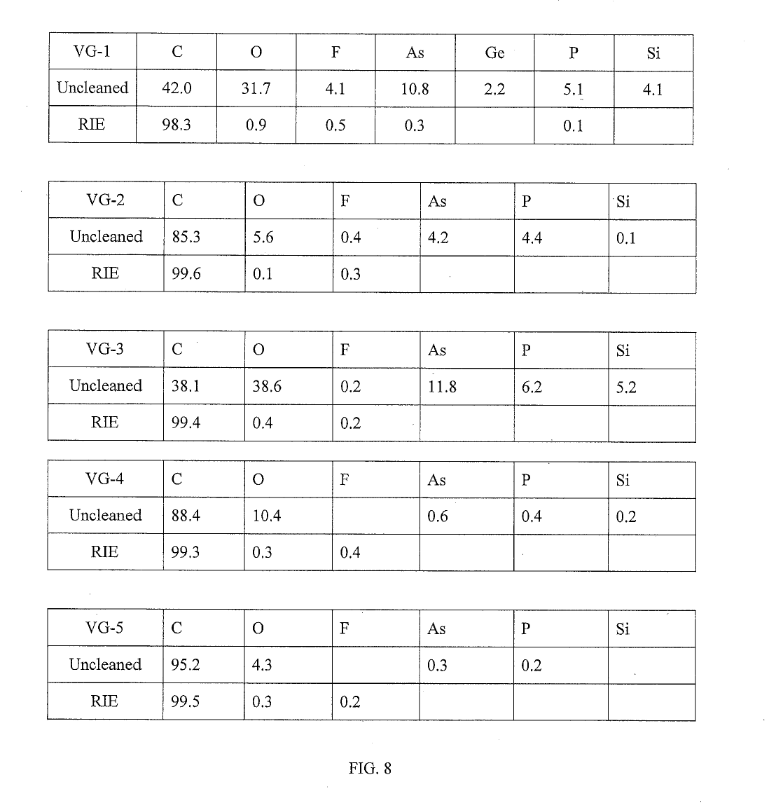

FIG. 8 shows results of cleaning the components of FIG. 7 using the reactive ion etch refurbishment in accordance with an embodiment of the invention, with the results given as EDS figures for atomic percent of each species present. As can be seen, the reactive ion etch (RIE) technique reduced the level of contaminants present and increased the proportion of carbon in the components as compared with the same components when untreated (“RIE” versus “untreated”). For example, refurbished components in accordance with an embodiment of the invention may comprise 99% or greater content of carbon and 1% or less content of fluorine, arsenic, germanium, phosphorous and silicon combined, by atomic percent.

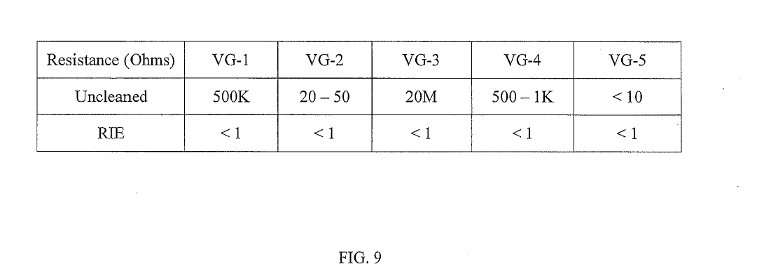

FIG. 9 shows further results of cleaning the components of FIG. 7 using the reactive ion etch refurbishment in accordance with an embodiment of the invention, with the results given as electrical resistances for each component. Resistances were measured by two probes on the side of each graphite component. The reactive ion etch technique reduced the resistance of the components as compared with the same components when untreated (“RIE” versus “untreated”).

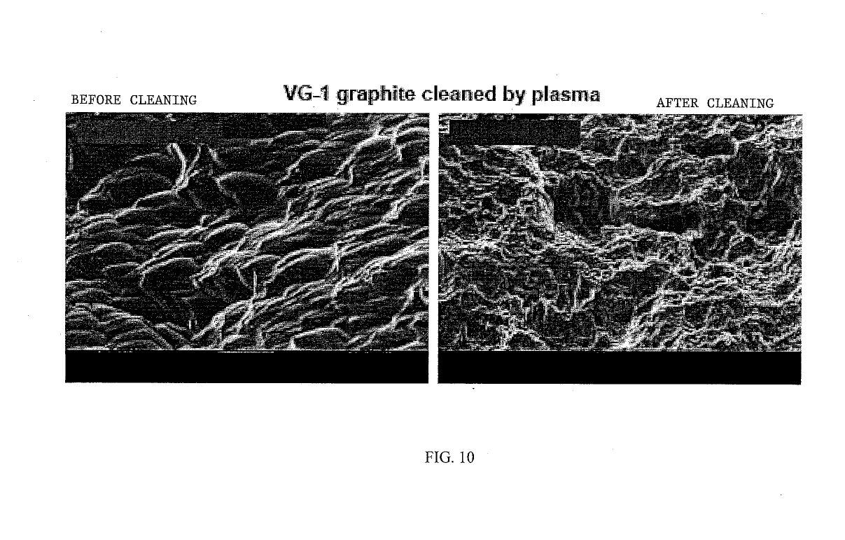

FIG. 10 is a scanning electron micrograph image of one of the components of FIG. 7 before and after reactive ion etch refurbishment in accordance with an embodiment of the invention. A significantly different microstructure can be seen. It was found that the reactive ion etch process removed both photoresist and metal contaminants from the component shown in FIG. 10.

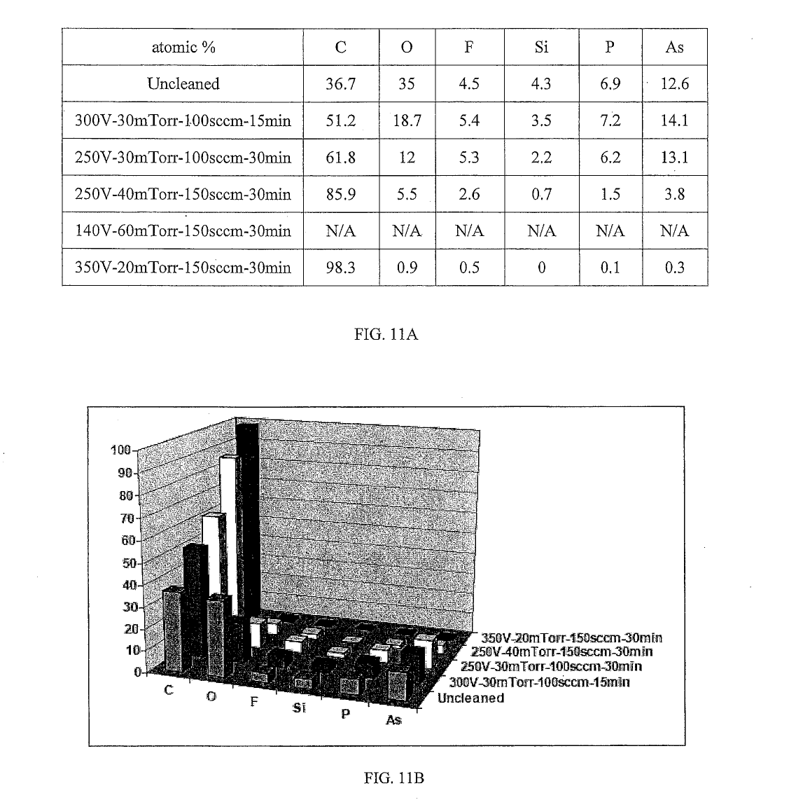

FIG. 11A is a chart showing the effects of several different reactive ion etch refurbishment procedures performed on the component shown in FIG. 10, and FIG. 11B is a diagram showing the results of FIG. 11A in graphical form, in accordance with an embodiment of the invention. The results shown in FIGS. 11A and 11B show the atomic percentages of carbon and the various contaminants present after reactive ion etch refurbishment. The reactive ion etch procedures used included (a) 300V, 30 mTorr, 100 sccm (standard cubic centimeter per minute) flow rate for 15 minutes; (b) 250 V, 30 mTorr, 100 sccm for 30 minutes; (c) 250 V, 40 mTorr, 150 sccm for 30 minutes; and (d) 350 V, 20 mTorr, 150 sccm for 30 minutes. Of these, the best results were obtained with reactive ion etch procedures (d) and (c), respectively. The 100 sccm procedures used Argon at 20 sccm, Oxygen (O₂) at 15 sccm, and CF₄ at 65 sccm; while the 150 sccm procedures used Argon at 30 sccm, Oxygen (O₂) at 20 sccm, and CF₄ at 150 sccm.

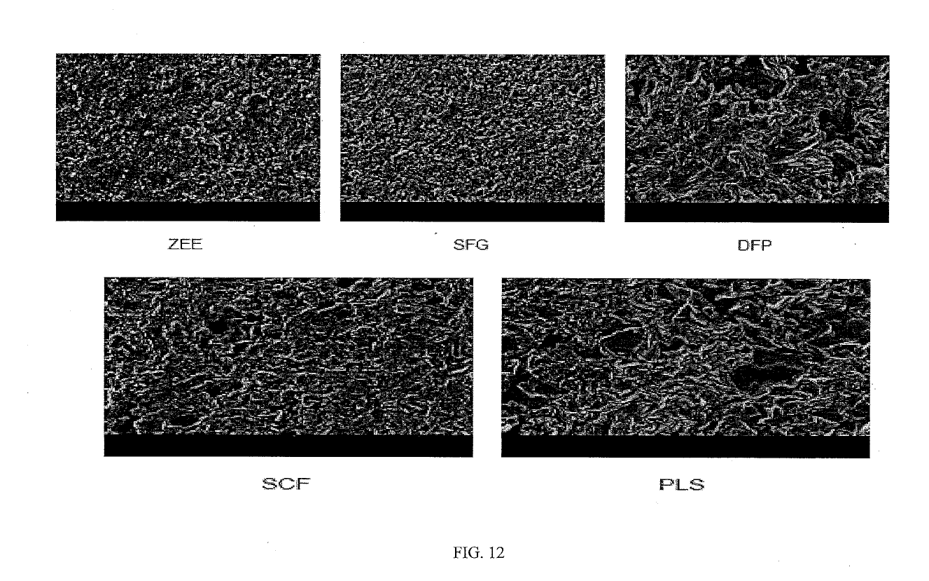

In accordance with an embodiment of the invention, a reactive ion etch process may be used to pre-process graphite to be used in a liner, during the manufacturing process of the liner. After pre-treatment with the reactive ion etch process, the graphite may then be coated with a highly conductive coating, such as those set forth herein. FIG. 12 is a scanning electron micrograph image of the microstructure of several graphite samples prior to pre-cleaning by the reactive ion etch process in accordance with an embodiment of the invention. Reactive ion etch (RIE) was used to clean the graphite. Variables such as gas flow, time, voltage and pressure of the RIE process were adjusted. Responses such as the etching rate (as measured by the step height and weight loss of the graphite), the surface roughness, and the particulation of the graphite were determined. The graphite samples were also characterized by scanning electron micrograph.

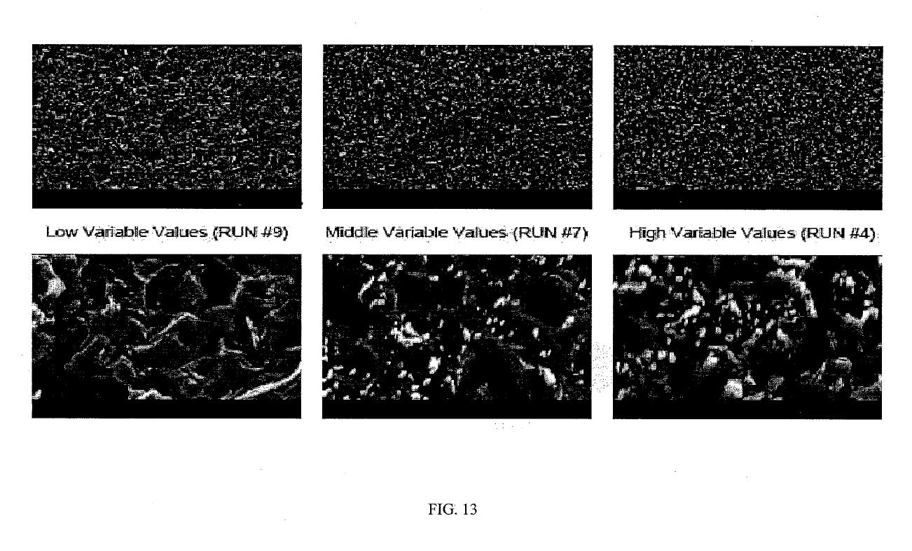

FIG. 13 is a scanning electron micrograph image of the microstructure of one of the graphite samples (labeled ZEE in FIG. 12) after pre-cleaning by the reactive ion etch process in accordance with an embodiment of the invention. Samples from several different runs are shown, with a lower resolution in the top row (10 μm scale) and a higher resolution in the bottom row (1 μm scale) of the images. The changed morphology relative to FIG. 12 can be seen by a comparison of the two figures.

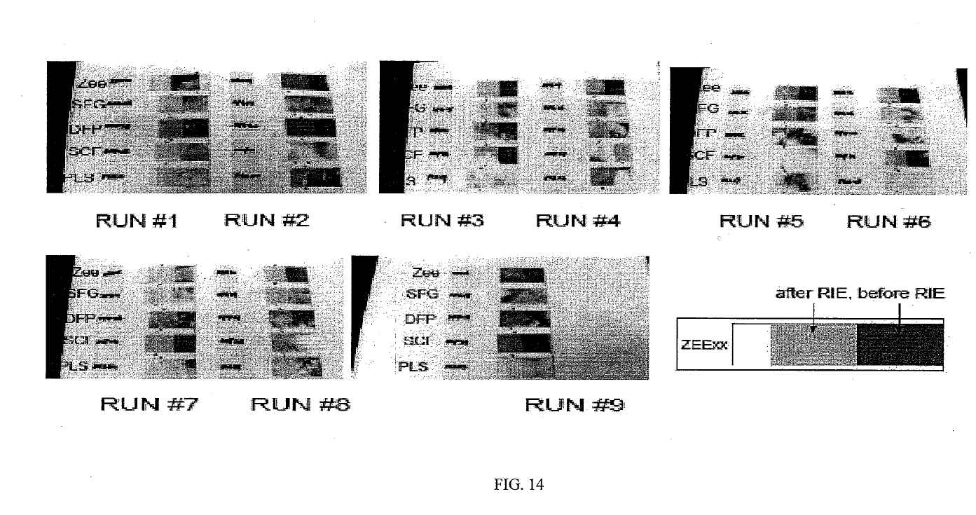

FIG. 14 is a set of photographs of the results of an optical density tape test performed on the graphite samples of FIG. 12 before and after reactive ion etch treatment in accordance with an embodiment of the invention. As indicated by the schematic diagram in the lower right of the figure, for each of the samples, an area on the right of each tape shows the levels of particulation before treatment, an area in the middle of each tape shows the levels of particulation after treatment, and an area on the left of each tape refers to the type of graphite sample from FIG. 12. The lighter appearance of the middle sections of each tape show that the reactive ion etch treatment is effective in reducing levels of particulation produced by the graphite. The tape test was performed by taping both un-etched and etched graphite, and peeling the tape off the surface. The optical density of the tapes was measured using a densitometer. A reduction in particulation was found for all graphite samples after reactive ion etch cleaning.

In accordance with an embodiment of the invention, reactive ion etch manufacturing and refurbishment of graphite may be used to produce a low level of particulation of the graphite. For example, a graphite article manufactured or refurbished using reactive ion etch may comprise a surface producing greater than about 70% densitometry transmission using an optical density tape test; including a surface producing greater than about 80% densitometry transmission. Further, such transmission percentages may be obtained after exposure to an ion beam, which may have been directed at the graphite article at a perpendicular or other incident angle.

In accordance with an embodiment of the invention, the etching rate (in μm of graphite per minute) of a reactive ion etch process on graphite was investigated. Etching rate was calculated using step height measurement. Power, pressure, Argon to Oxygen ratio and time were found to be significant, with a two-way interaction between Argon to Oxygen ratio and power being found to be significant in determining etching rate. Power, pressure, Argon to Oxygen ratio and time were all found to have a linear effect on etching rate of the graphite. Further, etching rate was investigated using weight loss measurement in milligram per minute of graphite. Similar main effects for etching rate were found as for the findings that were based on the step height measurement, although only power was found to have a significant effect.

In accordance with an embodiment of the invention, a reactive ion etch refurbishment may be performed using an argon/oxygen plasma; or using an argon/oxygen/CF₄ plasma, which may use about 10% CF₄, about 30% CF₄ or about 60% CF₄. Where an argon/oxygen/CF₄ plasma is used, better results have been found with increasing percentages of CF₄. In particular, a reactive ion etch refurbishment may use about 20% Argon, about 15% Oxygen, about 65% CF₄, about 700V DC-bias voltage, about 15 mTorr pressure and radio frequency plasma at 13.56 MHz for about 1 hour. For example, a reactive ion etch unit may use about 20 sccm Argon at about 1 mTorr pressure; about 15 sccm Oxygen at about 0.5 mTorr pressure; and about 65 sccm CF₄ at about 1.5 mTorr pressure. Generally, in accordance with an embodiment of the invention, the frequency of the plasma may be adjusted according to the pressure used. For instance, in some pressure regimes (e.g., 15 mTorr), radio frequency plasma may be used, for example at 13.56 MHz, 52 MHz or any other frequency permitted by communications regulatory agencies. In other pressure regimes (e.g., 200 mTorr), a low frequency power supply may be used, for example a frequency in the 100 kHz range. It will be appreciated that other frequencies and pressures may be used.

An embodiment according to the invention may use reactive ion etch to perform a pre-treatment of graphite material prior to coating of the graphite material. Such a pre-treatment allows the removal of free surface particles; enhances the adhesion strength of the coating on the graphite; and retains the graphite surface finishing and dimension specifications. The reactive ion etch process parameters may include low temperature deposition etching (for example, less than about 150° C.); radio frequency or low frequency power; argon, oxygen and/or nitrogen gaseous precursors; and varied voltages, pressures, gaseous precursor flow rates and etching times. In one embodiment, the gases are argon and oxygen; the open baffle partial pressure is about 1.5 mTorr for argon and about 0.5 mTorr for oxygen; the process baffle pressure is about 5 mTorr; the power is radio frequency at about 500 W; and the time is about 10 minutes.

A further embodiment according to the invention may use reactive ion etch to refurbish used graphite. Such a refurbishment technique allows the removal of contamination by III-V elements that occurs during ion implantation; and extends the total lifetime of graphite by recycling it. Preferably, a graphite refurbishment technique should effectively remove contamination of III-V elements that occurs during ion implantation; should be a non-abrasive cleaning process; should use no metal-containing species in the cleaning process; and should retain as much as possible of the original graphite surface finishing and dimension specifications. The reactive ion etch process parameters may include low temperature deposition etching (for example, less than about 150° C.); radio frequency or low frequency power; argon, oxygen, nitrogen, fluorine and/or chlorine gaseous precursors; and varied voltages, pressures, gaseous precursor flow rates and cleaning times. In one embodiment, the gases are argon, oxygen and carbon tetrafluoride (CF₄); the open baffle partial pressure is about 1 mTorr for argon; about 0.5 mTorr for oxygen and about 1.5 mTorr for CF₄; the process baffle pressure is about 5-15 mTorr; the power is radio frequency at about 500 W; and the time is about 10 to 30 minutes. In addition, other techniques of cleaning the used graphite material may be combined with a reactive ion etch technique in accordance with an embodiment of the invention. Such other techniques may, for example, be performed prior to the reactive ion etch cleaning; and may include aqueous ultrasonic cleaning, high temperature purification, dry ice (CO₂) blasting, bead blasting and/or slurry blasting. More generally, in accordance with an embodiment of the invention, any suitable reactive ion etch process may be used. Principally, reactive ion etch includes the use of an energetic ion, which may be produced, for example, in a plasma, which is an ionized state of gas that makes particles reactive, and typically requires a vacuum or other rarefied atmosphere to allow the particles to have a sufficiently long lifetime to reach the substrate. Any suitable technique of generating the plasma may be used.

An embodiment according to the invention for pre-cleaning or refurbishment may be used on a graphite article coated with a thin layer of highly conductive material, for example a liner for a process chamber. In accordance with an embodiment of the invention, the underlying graphite of the liner may be produced based on the technique for selection of a graphite starting material, and purification of the graphite starting material, that are described above.

In a further embodiment according to the invention, a refurbishment process may remove trace amounts of at least one substance imparted from an ion source, for example a substance that was deposited in use of the article in an ion implant process. The substance to be removed may comprise at least one of a photoresist, boron, arsenic, silicon and phosphorus. Further, the substance to be removed may comprise at least one of a backsputtered material from an ion implant process and an evaporated material from an ion implant process. Where a coated article is refurbished, the graphite may comprise trace amounts of at least one substance imparted from an ion source, while a new conductive coating overlaying at least a portion of the graphite does not comprise the trace amounts of the at least one substance imparted from the ion source. For example, such a conductive coating may include any of the conductive coatings set forth herein.

In accordance with an embodiment of the invention, a liner coated with a coating discussed herein, or a pre-cleaning manufacturing step or a refurbishment technique as discussed herein, may be used for liner components that are removed as separate pieces from a process chamber during scheduled maintenance, for example for refurbishment. For example, a liner according to an embodiment of the invention, and/or such techniques according to an embodiment of the invention, may be used as, and/or to manufacture or refurbish, the type of liner set forth in U.S. Patent App. Pub. No. 2009/0179158 A1 of Stone et al., the disclosure of which is hereby incorporated herein by reference in its entirety, in which a liner is removed from the face of the vacuum chamber during maintenance.

Further, in accordance with an embodiment of the invention, a reactive ion etch pre-cleaning manufacturing step or refurbishment technique as set forth herein, may be used with any of the coated graphite articles or conductive coatings set forth herein. For example, a reactive ion etch manufacturing step or refurbishment technique set forth herein may be used with a coated graphite article in which the conductive coating comprises a through-thickness resistance of less than about 50 ohms as measured through the thickness of the graphite and the conductive coating. For example, such a reactive ion etch manufacturing step or refurbishment technique set forth herein may be used with a coated graphite article in which the coating comprises silicon carbide, non-stoichiometric silicon carbide, amorphous hydrogenated silicon carbide (a-SiC:H), diamond-like carbon, amorphous carbon or amorphous hydrogenated nitrogen-containing carbon, or other compositions set forth herein, and including with thicknesses and other characteristics set forth herein.

It will be appreciated that a coated graphite article, and/or a pre-cleaned or refurbished graphite article, in accordance with an embodiment of the invention may be used in a variety of other applications than in ion implant, for example in plasma doping systems or in any other setting in which a graphite article with a high conductivity and/or low particulating coating may be desirable.

The teachings of all patents, published applications and references cited herein are incorporated by reference in their entirety.

While this invention has been particularly shown and described with references to example embodiments thereof, it will be understood by those skilled in the art that various changes in form and details may be made therein without departing from the scope of the invention encompassed by the appended claims.

1. A coated graphite article, the article comprising:
graphite; and
a conductive coating overlaying at least a portion of the graphite, the conductive coating comprising a through-thickness resistance of less than about 50 ohms as measured through the thickness of the graphite and the conductive coating.

2. An article according to claim 1, wherein the article comprises a liner of a vacuum chamber.

3-4. (canceled)

5. An article according to claim 1, wherein the conductive coating comprises less than about 1 part per million total impurity level.

6-13. (canceled)

14. An article according to claim 1, wherein the conductive coating comprises a thickness of less than about 1000 nm; a thickness of more than about 100 nm; a thickness of within about 50 nm of about 250 nm; or a thickness of within about 50 nm of about 500 nm.

15. An article according to claim 1, wherein the article comprises a surface producing greater than about 70% densitometry transmission using an optical density tape test.

16. (canceled)

17. An article according to claim 1, wherein the conductive coating comprises carbon.

18-23. (canceled)

24. An article according to claim 1, the graphite comprising trace amounts of at least one substance imparted from an ion source;
the conductive coating not comprising the trace amounts of the at least one substance imparted from the ion source; and
the article comprising a surface producing greater than about 70% densitometry transmission using an optical density tape test.

25. A method for manufacturing a graphite article comprising a conductive coating, the method comprising:
treating graphite of the article with a reactive ion etch process; and
after treating the graphite with the reactive ion etch process, applying the conductive coating over at least a portion of the graphite.

26. A method according to claim 25, wherein treating the article with the reactive ion etch process comprises treating the article with an Argon Oxygen plasma.

27-31. (canceled)

32. A method according to claim 25, wherein the conductive coating comprises a through-thickness resistance of less than about 50 ohms as measured through the thickness of the graphite and the conductive coating.

33-36. (canceled)

37. A method for refurbishing a graphite article comprising graphite and an overlaying conductive coating, the method comprising:
removing at least a portion of the overlaying conductive coating of the graphite article with a reactive ion etch process; and
applying a new conductive coating over the at least a portion of the graphite.

38. A method according to claim 37, wherein the reactive ion etch process comprises treating the article with an Argon Oxygen plasma.

39. A method according to claim 37, wherein at least one of the graphite and the at least a portion of the conductive coating that is removed comprises trace amounts of at least one substance imparted from an ion source.

40-43. (canceled)

44. A method according to claim 37, wherein the reactive ion etch process comprises using at least one of an argon gaseous precursor, an oxygen gaseous precursor, a nitrogen gaseous precursor, a fluorine gaseous precursor, and a chlorine gaseous precursor.

45-52. (canceled)

53. A coated graphite article, the article comprising:
graphite comprising trace amounts of at least one substance imparted from an ion source; and
a conductive coating overlaying at least a portion of the graphite, the conductive coating not comprising the trace amounts of the at least one substance imparted from the ion source;
the article comprising a surface producing greater than about 70% densitometry transmission using an optical density tape test.

54-55. (canceled)

56. A coated graphite article according to claim 53, wherein the substance imparted from the ion source comprises at least one of a backsputtered material from an ion implant process and an evaporated material from an ion implant process.
